(19) United States
(12) Patent Application Publication
(10) Pub. No.: US 2022/0189856 A1
(43) Pub. Date: Jun. 16, 2022

(54) DIE ATTACHMENT FOR SEMICONDUCTOR DEVICE PACKAGING AND METHOD THEREFOR

(71) Applicant: NXP B.V., San Jose, CA (US)

(72) Inventors: Yeou Chian Chang, Taipei City (TW); Chao Hui Huang, Kaohsiung City (TW)

(21) Appl. No.: 17/118,865

(22) Filed: Dec. 11, 2020

(51) Int. Cl. H01L 23/495; H01L 23/31; H01L 21/56; H01L 23/36; H01L 23/532

(52) U.S. Cl. CPC H01L 23/49503; H01L 23/49575; H01L 23/31; H01L 23/53228; H01L 23/49541; H01L 23/36; H01L 21/56

(57) ABSTRACT

A method of manufacturing a semiconductor device is provided. The method includes forming a package leadframe including leads and a die paddle. A cavity is formed in the die paddle. Sidewall and bottom surfaces of the cavity are plated with a solder alloy material. A semiconductor die is attached to the bottom surface of the cavity by way of a thermal cycle. A molding compound encapsulates the semiconductor die, a portion of the leads, and a portion of the die paddle.

### BACKGROUND

### Field

This disclosure relates generally to semiconductor devices, and more specifically, to die attachment for semiconductor device packaging.

### Related Art

Semiconductor devices are often found in a large spectrum of electronic products—from sewing machines to washing machines, from automobiles to cellular telephones, and so on. Many of these semiconductor devices are sensitive to temperature, pressure, moisture and other environmental conditions. Such sensitives often affect the performance and reliability of those semiconductor devices. However, as technology progresses, semiconductor manufacturing continues to seek ways to improve performance and reliability in these semiconductor devices.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates, in a simplified plan view, a leadframe for an example semiconductor device at a stage of manufacture in accordance with an embodiment.

FIG. 2 through FIG. 8 illustrate, in simplified cross-sectional views, the example semiconductor device at stages of manufacture in accordance with an embodiment.

### DETAILED DESCRIPTION

Generally, there is provided, a die attachment method and structure for semiconductor device packaging suitable for package types with solder alloy die attach material. A die paddle of a package leadframe is formed having a cavity. The sidewalls and bottom surface of the cavity are selectively plated with a solder alloy material. A semiconductor die is attached at the bottom surface of the cavity during a thermal cycle. During the thermal cycle, the die paddle is heated to cause the solder alloy to reflow. As the solder reflows, a superior void-free die attachment is formed. By eliminating voids in the die attachment materials, especially for power device packages, higher reliability, performance, and manufacturing yields can be realized.

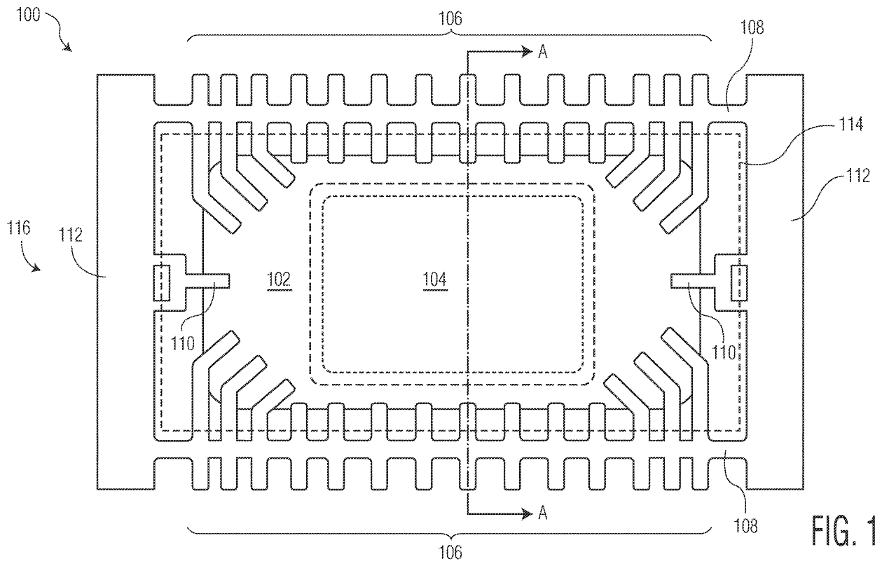

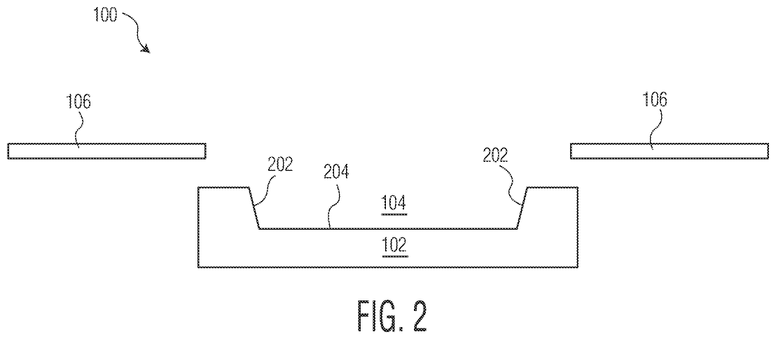

FIG. 1 illustrates, in a simplified plan view, a leadframe 116 for an example semiconductor device 100 at a stage of manufacture in accordance with an embodiment. At this stage, semiconductor device 100 includes a leadframe 116. The leadframe 116 includes a die paddle 102, a cavity 104 formed in the die paddle, a plurality of conductive leads 106, dam bars 108 interconnected to the plurality of leads 106 and side rails 112, and tie bars 110 extending from side rails 112. The leadframe 116 may be formed from any suitable electrically conductive materials, such as copper, silver, nickel, aluminum, or iron, or alloys thereof, for example. The conductive metal may be bare, partially plated, or plated with another metal or an alloy such as iron/nickel alloy, silver, gold, copper, or the like. In this embodiment, the leadframe 116 may be characterized as a power device leadframe such as heatsink small outline package (HSOP) leadframe. Other power device leadframes are anticipated such as dual in-line bent single in-line (DIL-bent-SIL or DBS) package leadframes, for example. A dashed outline label 114 indicates an outer perimeter location of an encapsulant at a subsequent stage of manufacture. Cross-sectional views of semiconductor device 100 taken along line A-A are shown in example stages of manufacture depicted in FIG. 2 through FIG. 8.

The die paddle 102 may be formed having any suitable shape or size. The cavity 104 formed in the die paddle 102 is configured for an attachment of a semiconductor die. The cavity 104 may be formed by way of a punch process or by way of an etch process. In this embodiment, the die paddle 102 is formed separately and connected to the leadframe 116 by way of tie bar welds. The plurality of leads 106 are configured and arranged to couple electrical signals between external (e.g., printed circuit board) locations of a mounted semiconductor device and internal locations such as bond pads on a semiconductor die attached to the die paddle 102, for example.

FIG. 2 illustrates, in a simplified cross-sectional view, the example semiconductor device 100 taken along line A-A at a stage of manufacture in accordance with an embodiment. The semiconductor device 100 depicted in FIG. 2 includes the conductive leads 106 and the die paddle 102. At this stage, the cavity 104 is formed in the die paddle 102. The cavity 104 includes sidewalls 202 and bottom 204 surfaces. The cavity 104 may be formed by way of a punch process or by way of an etch process. In some embodiments, the die paddle 102 is further configured as a heat spreader or heatsink configured for dissipation of heat generated from an attached semiconductor die. For example, this configuration of the die paddle 102 may be advantageous for power devices which generate a significant amount of heat.

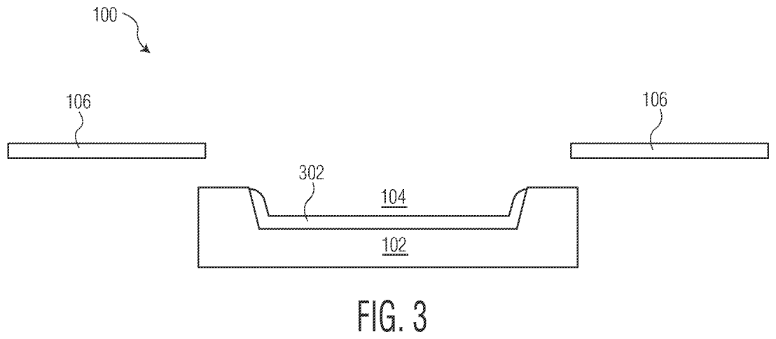

FIG. 3 illustrates, in a simplified cross-sectional view, the example semiconductor device 100 taken along line A-A at a subsequent stage of manufacture in accordance with an embodiment. At this stage, the semiconductor device 100 depicted in FIG. 3 includes the conductive leads 106 and the die paddle 102 with the cavity 104 having plated surfaces. The sidewall and bottom surfaces of the cavity 104 are selectively plated with a solder alloy. In this embodiment, approximately the entire sidewall and bottom surfaces of the cavity are plated with the solder alloy. The solder alloy may be formed from materials such as tin, lead, copper, silver, gold, zinc, nickel, and bismuth materials for example.

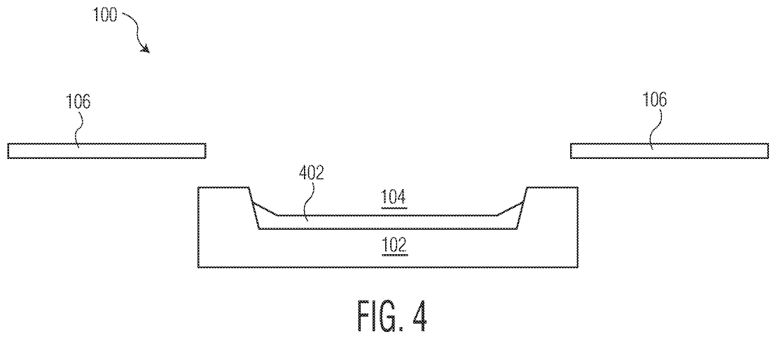

FIG. 4 illustrates, in a simplified cross-sectional view, the example semiconductor device 100 taken along line A-A at a subsequent stage of manufacture in accordance with an embodiment. At this stage, the semiconductor device 100 depicted in FIG. 4 includes the conductive leads 106 and the die paddle 102 with the cavity 104 having reflowed plated surfaces. The die paddle 102 is subjected to a thermal cycle whereby heat applied to the die paddle 102 causes the solder alloy on the surfaces of the cavity 104 to wet and reflow. The reflowed solder alloy 402 remains on a lower portion of the sidewall surfaces while an upper portion of the sidewall surfaces is substantially clear of the solder alloy.

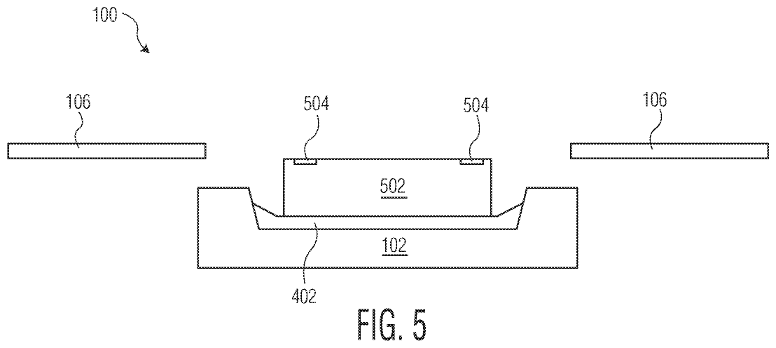

FIG. 5 illustrates, in a simplified cross-sectional view, the example semiconductor device 100 taken along line A-A at a subsequent stage of manufacture in accordance with an embodiment. At this stage, the semiconductor device 100 depicted in FIG. 5 includes a semiconductor die 502 attached to the die paddle 102 by way of the reflowed solder alloy 402. A bottom surface of the semiconductor die 502 is attached to the bottom of the cavity of the die paddle 102 by way of the reflowed solder alloy 402. For example, during the thermal cycle of the stage depicted in FIG. 4 or a subsequent thermal cycle, the reflowed solder alloy 402 is in a molten state allowing for attachment of the semiconductor die 502 to the bottom surface of the cavity. The semiconductor die 502 may be formed from any suitable semiconductor material, such as silicon, germanium, gallium arsenide, gallium nitride and the like. Semiconductor die 502 may include circuitry such as high voltage circuits capable of generating heat.

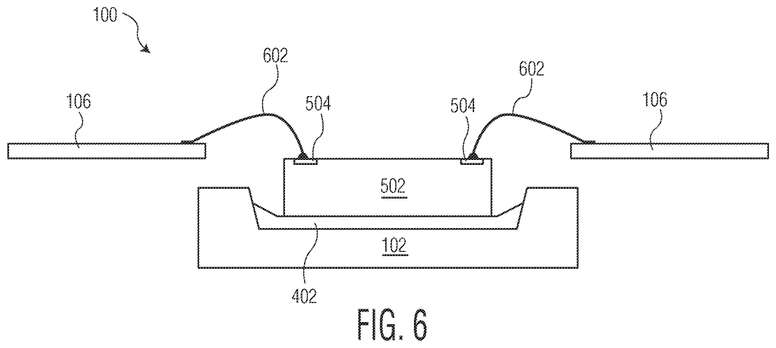

FIG. 6 illustrates, in a simplified cross-sectional view, the example semiconductor device 100 taken along line A-A at a subsequent stage of manufacture in accordance with an embodiment. At this stage, the semiconductor device 100 depicted in FIG. 6 includes the semiconductor die 502 attached to the die paddle 102 and interconnected to the conductive leads 106 by way of bond wires 602. The semiconductor die 502 includes bond pads 504 formed at a top surface. Bond wire 602 have a first end connected to the die pads 504 on the semiconductor die 502 and a second end connected to the conductive leads 106. The bond wires 602 may be formed from a suitable metal material such as copper, silver, gold, or aluminum, for example.

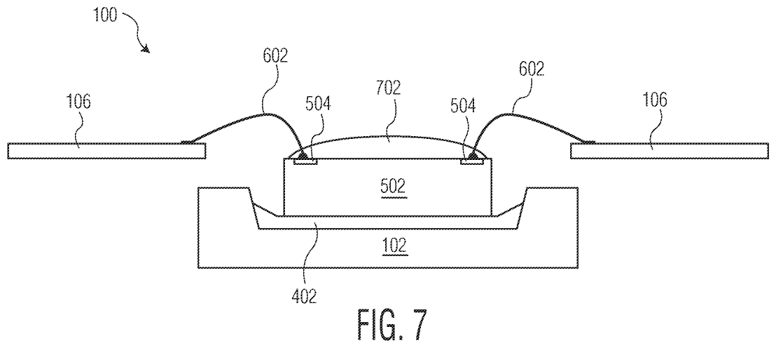

FIG. 7 illustrates, in a simplified cross-sectional view, the example semiconductor device 100 taken along line A-A at a subsequent stage of manufacture in accordance with an embodiment. At this stage, the semiconductor device 100 depicted in FIG. 7 includes a die coating 702 formed over the semiconductor die 502 after the wire bonding stage depicted in FIG. 6. The die coating 702 is applied to the top surface of the semiconductor die 502 using known methods and techniques. The die coating 702 may be formed from a silicone gel or polyimide material, for example. In this embodiment, the die coating 702 may serve to substantially isolate the top surface of the semiconductor die 502 from a molding compound encapsulant formed in a subsequent stage, thus minimizing stress on the semiconductor die 502 and improving reliability.

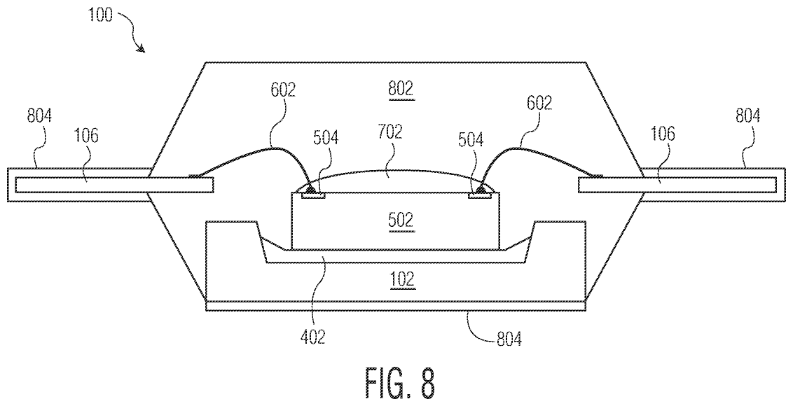

FIG. 8 illustrates, in a simplified cross-sectional view, the example semiconductor device 100 taken along line A-A at a subsequent stage of manufacture in accordance with an embodiment. At this stage, the semiconductor device 100 depicted in FIG. 8 includes an encapsulant 802 encapsulating portions of the semiconductor die 502, die paddle 102, and conductive leads 106. The encapsulant 802 may be an epoxy molding compound dispensed during an injection molding encapsulation operation, for example. In this embodiment, a bottom surface of the die paddle 102 may remain exposed after encapsulating with the encapsulant 804. For example, with the bottom surface of the die paddle 102 exposed, connection to an external heatsink or other heat dissipation structure is facilitated. After encapsulating portions of the semiconductor die 502, die paddle 102, and conductive leads 106 with the encapsulant 804, exposed portions of the conductive leads 106 and bottom surface of the die paddle 102 are plated with a conductive material. For example, the exposed portions of the conductive leads 106 and bottom surface of the die paddle 102 may be electroplated with a tin alloy material to facilitate solder adhesion. In a subsequent stage, the semiconductor device 100 may be trimmed and formed to singulate the device and to shape the conductive leads in a manner suitable for attachment to a printed circuit board.

Generally, there is provided, a method including forming a package leadframe, the package leadframe including leads and a die paddle; forming a cavity in the die paddle; plating sidewall and bottom surfaces of the cavity with a solder alloy material; attaching a semiconductor die to the bottom surface of the cavity by way of a thermal cycle; and encapsulating with a molding compound the semiconductor die, a portion of the leads, and a portion of the die paddle. The method may further include connecting a die pad on the semiconductor die with a lead of the package leadframe by way of a bond wire. The method may further include applying a die coating material to a top surface of the semiconductor die before encapsulating with the molding compound. The thermal cycle may include heating the die paddle sufficient to reflow the solder alloy. The leads and the die paddle may be formed from a copper or copper alloy material. The die paddle may be configured to dissipate heat generated by the semiconductor die. The method may further include after encapsulating with the molding compound, plating exposed surfaces of the leadframe leads and the die paddle with a tin material. The package leadframe may be characterized as a heatsink small outline package (HSOP) leadframe.

In another embodiment, there is provided, a semiconductor device including a package leadframe having a plurality of conductive leads and a die paddle; a cavity formed in the die paddle, the cavity having sidewall and bottom surfaces; a solder alloy formed on a portion of the sidewall surfaces and on the bottom surface of the cavity; a semiconductor die attached to the bottom surface of the cavity by way of the solder alloy; and a molding compound encapsulating the semiconductor die, a portion of the conductive leads, and a portion of the die paddle. The die paddle may be configured to dissipate heat generated by the semiconductor die. The semiconductor device may further include a die coating material applied to a top surface of the semiconductor die. The leads and the die paddle may be formed from a copper or copper alloy material. The semiconductor device may further include a metal material plated on exposed surfaces of the plurality of conductive leads and the die paddle. The semiconductor device may further include a bond wire having a first end connected to a die pad on the semiconductor die and a second end connected to a lead of the plurality of conductive leads. The package leadframe may be characterized as a heatsink small outline package (HSOP) leadframe.

In yet another embodiment, there is provided, a method including providing a package leadframe including a plurality of conductive leads and a die paddle, the die paddle having a cavity formed in a top surface; plating sidewall and bottom surfaces of the cavity with a solder alloy material; attaching a semiconductor die to the bottom surface of the cavity while heating the die paddle to reflow the solder alloy; and encapsulating with a molding compound the semiconductor die, a portion of the leads, and a portion of the die paddle. The method may further include connecting by way of a bond wire a die pad on the semiconductor die with a lead of the plurality of conductive leads. The method may further include applying a die coating material to a top surface of the semiconductor die before encapsulating with the molding compound. The method may further include after encapsulating with the molding compound, plating exposed surfaces of the plurality of conductive leads and the die paddle with a tin material. The die paddle may be configured to dissipate heat generated by the semiconductor die.

By now it should be appreciated that there has been provided, a die attachment method and structure for semiconductor device packaging suitable for package types with solder alloy die attach material. A die paddle of a package leadframe is formed having a cavity. The sidewalls and bottom surface of the cavity are selectively plated with a solder alloy material. A semiconductor die is attached at the bottom surface of the cavity during a thermal cycle. During the thermal cycle, the die paddle is heated to cause the solder alloy to reflow. As the solder reflows, a superior void-free die attachment is formed. By eliminating voids in the die attachment materials, especially for power device packages, higher reliability, performance, and manufacturing yields can be realized.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method comprising:
forming a package leadframe, the package leadframe including leads and a die paddle;
forming a cavity in the die paddle;
plating sidewall and bottom surfaces of the cavity with a solder alloy material;
attaching a semiconductor die to the bottom surface of the cavity by way of a thermal cycle; and
encapsulating with a molding compound the semiconductor die, a portion of the leads, and a portion of the die paddle.

2. The method of claim 1, further comprising connecting a die pad on the semiconductor die with a lead of the package leadframe by way of a bond wire.

3. The method of claim 1, further comprising applying a die coating material to a top surface of the semiconductor die before encapsulating with the molding compound.

4. The method of claim 1, wherein the thermal cycle comprises heating the die paddle sufficient to reflow the solder alloy.

5. The method of claim 1, wherein the leads and the die paddle are formed from a copper or copper alloy material.

6. The method of claim 1, wherein the die paddle is configured to dissipate heat generated by the semiconductor die.

7. The method of claim 1, further comprising after encapsulating with the molding compound, plating exposed surfaces of the leadframe leads and the die paddle with a tin material.

8. The method of claim 1, wherein the package leadframe is characterized as a heatsink small outline package (HSOP) leadframe.

9. A semiconductor device comprising:
a package leadframe having a plurality of conductive leads and a die paddle;
a cavity formed in the die paddle, the cavity having sidewall and bottom surfaces;
a solder alloy formed on a portion of the sidewall surfaces and on the bottom surface of the cavity;
a semiconductor die attached to the bottom surface of the cavity by way of the solder alloy; and
a molding compound encapsulating the semiconductor die, a portion of the conductive leads, and a portion of the die paddle.

10. The semiconductor device of claim 9, wherein the die paddle is configured to dissipate heat generated by the semiconductor die.

11. The semiconductor device of claim 9, further comprising a die coating material applied to a top surface of the semiconductor die.

12. The semiconductor device of claim 9, wherein the leads and the die paddle are formed from a copper or copper alloy material.

13. The semiconductor device of claim 9, further comprising a metal material plated on exposed surfaces of the plurality of conductive leads and the die paddle.

14. The semiconductor device of claim 9, further comprising a bond wire having a first end connected to a die pad on the semiconductor die and a second end connected to a lead of the plurality of conductive leads.

15. The semiconductor device of claim 9, wherein the package leadframe is characterized as a heatsink small outline package (HSOP) leadframe.

16. A method comprising:
providing a package leadframe including a plurality of conductive leads and a die paddle, the die paddle having a cavity formed in a top surface;
plating sidewall and bottom surfaces of the cavity with a solder alloy material;
attaching a semiconductor die to the bottom surface of the cavity while heating the die paddle to reflow the solder alloy; and
encapsulating with a molding compound the semiconductor die, a portion of the leads, and a portion of the die paddle.

17. The method of claim 16, further comprising connecting by way of a bond wire a die pad on the semiconductor die with a lead of the plurality of conductive leads.

18. The method of claim 16, further comprising applying a die coating material to a top surface of the semiconductor die before encapsulating with the molding compound.

19. The method of claim 16, further comprising after encapsulating with the molding compound, plating exposed surfaces of the plurality of conductive leads and the die paddle with a tin material.

20. The method of claim 16, wherein the die paddle is configured to dissipate heat generated by the semiconductor die.
